(19) United States
(12) Patent Application Publication
(10) Pub. No.: US 2023/0281357 A1
(43) Pub. Date: Sep. 7, 2023

(54) GENERATING SIMULATION ENVIRONMENTS FOR TESTING AV BEHAVIOUR

(71) Applicant: FIVE AI LIMITED, Bristol (GB)

(72) Inventors: Jonathan Forshaw, Berkhamsted (GB); Caspar De Haes, Letchworth (GB); Christopher Pearce, London (GB); Bradley Scott, Cambridge (GB)

(73) Assignee: FIVE AI LIMITED, Bristol (GB)

(21) Appl. No.: 18/008,140

(22) PCT Filed: May 27, 2021
(86) PCT No.: PCT/EP2021/064283

§ 371 Date: Dec. 2, 2022

(30) Foreign Application Priority Data
Jun. 3, 2020 (GB) 2008366.3
Jan. 29, 2021 (GB) 2101237.2

(51) Int. Cl. G06F 30/20; G06F 11/36

(52) U.S. Cl. CPC G06F 30/20; G06F 11/3664; G06F 11/3696

(57) ABSTRACT

A computer implemented method of generating a scenario to be run in a simulation environment for testing the behaviour of an autonomous vehicle is described. An image is rendered on a display. A user can mark multiple locations to create at least one path for an agent vehicle in the rendered image. A path is generated which passes through the locations and rendered on the display. A user can define at least one behavioural parameter for controlling behaviour of the agent vehicle associated with the at least one path when the scenario is run in a simulation environment. The scenario is recorded for future use.

### TECHNICAL FIELD

The present disclosure relates to the generation of scenarios for use in simulation environments for testing the behaviour of autonomous vehicles.

### BACKGROUND

There have been major and rapid developments in the field of autonomous vehicles. An autonomous vehicle is a vehicle which is equipped with sensors and control systems which enabled it to operate without a human controlling its behaviour. An autonomous vehicle is equipped with sensors which enable it to perceive its physical environment, such sensors including for example cameras, radar and lidar. Autonomous vehicles are equipped with suitably programmed computers which are capable of processing data received from the sensors and making safe and predictable decisions based on the context which has been perceived by the sensors. There are different facets to testing the behaviour of the sensors and control systems aboard a particular autonomous vehicle, or a type of autonomous vehicle.

Sensor processing may be evaluated in real-world physical facilities. Similarly, the control systems for autonomous vehicles may be tested in the physical world, for example by repeatedly driving known test routes, or by driving routes with a human on-board to manage unpredictable or unknown context.

Physical world testing will remain an important factor in the testing of autonomous vehicles capability to make safe and predictable decisions. However, physical world testing is expensive and time-consuming. Increasingly there is more reliance placed on testing using simulated environments. If there is to be an increase in testing in simulated environments, it is desirable that such environments can reflect as far as possible real-world scenarios. Autonomous vehicles need to have the facility to operate in the same wide variety of circumstances that a human driver can operate in. Such circumstances can incorporate a high level of unpredictability.

It is not viable to achieve from physical testing a test of the behaviour of an autonomous vehicle in all possible scenarios that it may encounter in its driving life. Increasing attention is being placed on the creation of simulation environments which can provide such testing in a manner that gives confidence that the test outcomes represent potential real behaviour of an autonomous vehicle.

For effective testing in a simulation environment, the autonomous vehicle under test (the ego vehicle) has knowledge of its location at any instant of time, understands its context (based on simulated sensor input) and can make safe and predictable decisions about how to navigate its environment to reach a pre-programmed destination.

Simulation environments need to be able to represent real-world factors that may change. This can include weather conditions, road types, road structures, road layout, junction types etc. This list is not exhaustive, as there are many factors that may affect the operation of an ego vehicle.

The present disclosure addresses the particular challenges which can arise in simulating the behaviour of actors in the simulation environment in which the ego vehicle is to operate. Such actors may be other vehicles, although they could be other actor types, such as pedestrians, animals, bicycles et cetera.

A simulator is a computer program which when executed by a suitable computer enables a sensor equipped vehicle control module to be developed and tested in simulation, before its physical counterpart is built and tested. A simulator provides a sensor simulation system which models each type of sensor with which the autonomous vehicle may be equipped. A simulator also provides a three-dimensional environmental model which reflects the physical environment that an automatic vehicle may operate in. The 3-D environmental model defines at least the road network on which an autonomous vehicle is intended to operate, and other actors in the environment. In addition to modelling the behaviour of the ego vehicle, the behaviour of these actors also needs to be modelled.

Simulators generate test scenarios (or handle scenarios provided to them). As already explained, there are reasons why it is important that a simulator can produce many different scenarios in which the ego vehicle can be tested. Such scenarios can include different behaviours of actors. The large number of factors involved in each decision to which an autonomous vehicle must respond, and the number of other requirements imposed on those decisions (such as safety and comfort as two examples) mean it is not feasible to write a scenario for every single situation that needs to be tested. Nevertheless, attempts must be made to enable simulators to efficiently provide as many scenarios as possible, and to ensure that such scenarios are close matches to the real world. If testing done in simulation does not generate outputs which are faithful to the outputs generated in the corresponding physical world environment, then the value of simulation is markedly reduced.

Scenarios may be created from live scenes which have been recorded in real life driving. It may be possible to mark such scenes to identify real driven paths and use them for simulation. Test generation systems can create new scenarios, for example by taking elements from existing scenarios (such as road layout and actor behaviour) and combining them with other scenarios. Scenarios may additionally or alternatively be randomly generated.

However, there is increasingly a requirement to tailor scenarios for particular circumstances such that particular sets of factors can be generated for testing. It is desirable that such scenarios may define actor behaviour.

### SUMMARY

According to one aspect of the disclosure there is provided a computer implemented method of generating a scenario to be run in a simulation environment for testing the behaviour of an autonomous vehicle, the method comprising:
rendering on a display of a computer device an image of an environment comprising a road layout,
receiving at an editing interface user input for marking multiple locations to create at least one path for an agent vehicle in the rendered image of the environment,
generating at least one path which passes through the multiple locations, and rendering the at least one path in the image,
receiving at the editing interface user input defining at least one behavioural parameter for controlling behaviour of the agent vehicle associated with the at least one path when the scenario is run in a simulation environment, and
recording the scenario comprising the environment, the marked path and the at least one behavioural parameter.

In some embodiments, the method comprises detecting that a user has selected one of the marked locations and has repositioned it in the image. A new path is generated which passes through the existing multiple locations and the repositioned location.

In some embodiments, a path generation is effected such as to generate a smoothed path which passes through some but not all of the existing multiple locations and close to others, such as to improve the trajectory of the path. In that case, in the following description where points are taken from the path for calculation purposes, these points may be points along the smoothed path or the marked locations. In some cases, the smoothed path may pass through none of the marked locations but may pass close to them.

In some embodiments, the method comprises detecting that a user has highlighted a set of adjacent locations of the multiple locations and repositioned that set. The path is generated passing through the existing multiple locations and the repositioned set of multiple locations. This makes it easier for a user who is editing the path to move the path.

The path may comprise at least one curved section.

The step of generating the path may comprise interpolating between the marked multiple locations to generate a continuous path which passes through the marked multiple locations. Conversely, as mentioned above, the generation of a path can comprise smoothing such an interpolated path.

The method may comprise detecting that a user has selected one of the marked locations and displaying at that selected location a path parameter of that marked location. The display may not be at the selected location, but may be somewhere else on the display of the user interface. The path parameter may be the agent position or a target or default speed.

The path parameter may be a default speed for an agent vehicle on the path when the scenario is run in an execution environment. As explained more fully herein, an agent vehicle may exhibit different speeds in a simulation, modified from the default speed.

In some embodiments, the step of rendering the image of the environment on the display comprises accessing an existing scenario from a scenario database and displaying that existing scenario on the display. The existing scenario may comprise a static layer for rendering static objects in the environment and a dynamic layer for controlling motion of moving agents in the environment.

A playback mode may be selected by the user in some embodiments at the editing interface. In the playback mode, motion of the agent vehicle is simulated according to the at least one path and the at least one behavioural parameter in the scenario.

In some embodiments, user input at the editing interface may define a target region, at least one trigger agent and at least on triggered action. When the scenario is run in a simulation environment, the presence of the target agent in the target region can be detected and can cause the triggered action to be effected. For example, when a certain vehicle (which could be the ego vehicle or another agent vehicle) is detected in the target region, motion of another vehicle in the scenario could be triggered, or the motion of the vehicle in the target region could be altered. There are many possible triggered actions which can enable many different scenarios to be generated.

The road layout has driveable tracks along which ego vehicles are intended to travel. The road layout might further comprise junctions and other environment objects which constitute obstacles for an ego vehicle. In many cases, scenarios require paths that do conform to driveable tracks of the road layout so as to represent the normal flow of traffic. However, it may be useful to have scenarios in which the path does not conform to the driveable track. For example, a scenario could represent a case where an agent vehicle has become out of control and has mounted the pavement or crossed at a traffic light junction.

The road layout may comprise at least one traffic junction. The path for the agent vehicle may traverse the junction in a manner likely to create a possible collision event with an ego vehicle on the road layout when the scenario is run in a simulation environment. It is often useful to generate scenarios which represent likely collision instances which an ego vehicle has to navigate.

Another aspect of the invention provides a computer system for generating a scenario to be run in a simulation environment for testing the behaviour of an autonomous vehicle, the computer system comprising:
a display configured to present an image of an environment comprising a road layout,
an editing interface configured to receive user input for marking multiple locations to create at least one path for an agent vehicle in the image of the environment and for defining at least one behavioural parameter for controlling behaviour of the agent vehicle associated with the at least one path when the scenario is run in a simulation environment,
a path generation module configured to generate at least one path which passes through the multiple locations,
a rendering module configured to render the at least one path in the image, and computer storage configured to record the scenario comprising the environment, the marked path and the at least one behavioural parameter.

A further aspect of the invention provides a computer program product comprising computer code stored on a computer readable medium which when executed by a computer implements the steps of any of the above-defined methods.

In some embodiments, the scenario may comprise a dynamic layer comprising parameters of a dynamic interaction of the agent vehicle and a static layer of the scenario comprising a static scene topology. The method may comprise searching a store of maps to access a map having a matching scene topology to the static scene topology; and generating a simulated version of the dynamic interaction of the scenario using the matching scene topology of the map. The scene topology may comprise a road layout which can be used additionally to a marked path in a scenario.

The method may comprise: accessing a computer store to retrieve one of multiple scene topologies held in the computer store, each having a topology identifier and each defining a road layout having at least one driveable lane associated with a lane identifier; receiving at a graphical user interface a first set of parameters defining an ego vehicle and its behaviour to be instantiated in the scenario, wherein the behaviour is defined relative to a driveable lane of the road layout, the driveable lane identified by its associated lane identifier.

For better understanding of the present invention and to show how the same may be carried into effect, reference will now be made, by way of example, to the accompanying drawings.

### BRIEF DESCRIPTION OF THE DRAWINGS

FIG. 1 illustrates a display of a user interface on which a path has been marked by a user;

FIG. 2A shows the display of the user interface with a location marked by a user for creating the path;

FIG. 2B shows the display of FIG. 2A indicating how a point has been moved by a user from one location to another location;

FIG. 3 illustrates how a path may be updated by moving multiple points simultaneously on the display;

FIG. 4 illustrates an interface which may be presented on the display to indicate behaviour assigned to an agent;

FIG. 5 is a schematic block diagram of a computer system for generating scenarios;

FIG. 6 is a schematic block diagram of a runtime stack for an autonomous vehicle;

FIG. 7 is a schematic block diagram of a testing pipeline;

FIG. 8 shows a highly schematic diagram of the process whereby the system recognises all instances of a parameterised road layout on a map.

FIG. 9 shows a map on which the blue overlays represent the instances of a parameterised road layout identified on the map in the process represented by FIG. 8.

### DETAILED DESCRIPTION

It is necessary to define scenarios which can be used to test the behaviour of an ego vehicle in a simulated environment. Scenarios are defined and edited in offline mode, where the ego vehicle is not controlled, and then exported for testing in the next stage of a testing pipeline 7200 which is described below.

A scenario comprises one or more agents (sometimes referred to as actors) travelling along one or more paths in a road layout. A road layout is a term used herein to describe any features that may occur in a driving scene, and in particular includes at least one track along which a vehicle is intended to travel in a simulation. That track may be a road or lane or any other driveable path. A road layout is displayed in a scenario to be edited as an image on which paths may be marked. Agents may comprise non-ego vehicles or other road users such as cyclists and pedestrians. The scene may comprise one or more road features such as roundabouts or junctions. These agents are intended to represent real-world entities encountered by the ego vehicle in real-life driving situations. The present description allows the user to modify the motion of these agents to present more challenging conditions to the ego vehicle for testing.

The present description relates to an editing system having a scenario builder to extract and create abstract or concrete scenarios to obtain a large verification set for testing the ego vehicle. New test cases can be created on newly created or imported scenarios by creating, moving or re-ordering agents within the scene. Path parameters such as speeds and starting positions of agents can be user defined and/or altered, and agent paths can be repositioned to adjust the complexity of a scenario as it will be presented to an ego vehicle.

As described more fully herein, an existing scenario can be downloaded from a scenario database 508 for editing, for example a road layout scene of a junction such as a roundabout. The scene can be inspected and run in a playback mode of the editing system to identify what changes may be needed. Editing is carried out in an offline mode where the ego vehicle is not controlled in playback. In one example use case the ego vehicle's entry window into the roundabout is reduced in the scene by re-ordering agent (actor) vehicles in the scene. This may be achieved in an editing mode by assigning behaviours to an agent vehicle on a path displayed in the scene. The path may be repositioned in the scene by allowing the editor user to select one or more marked locations on the path and reposition them on the display. The behaviour may include an adaptive cruise control behaviour to control speed and distance between multiple agent vehicles on the same path. The editing system enables a user to switch from editing mode to playback mode to observe the effect of any changes they have made to the scenario.

Before further describing the editing system, a simulation system and its purpose will be described. Path parameters and/or behaviour parameters assigned during editing are used as motion data/behaviour data in a simulation as described below.

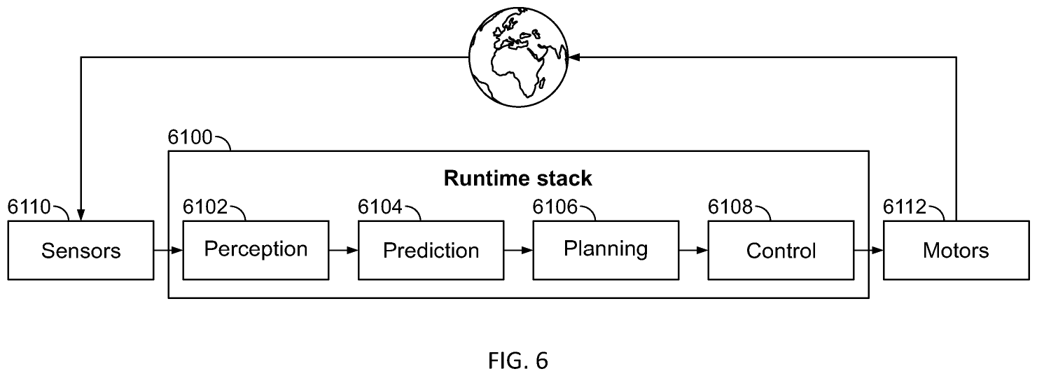

FIG. 6 shows a highly schematic block diagram of a runtime stack 6100 for an autonomous vehicle (AV), also referred to herein as an ego vehicle (EV). The run time stack 6100 is shown to comprise a perception system 6102, a prediction system 6104, a planner 6106 and a controller 6108.

In a real-world context, the perception system 6102 would receive sensor outputs from an on-board sensor system 6110 of the AV and uses those sensor outputs to detect external agents and measure their physical state, such as their position, velocity, acceleration etc. The on-board sensor system 6110 can take different forms but generally comprises a variety of sensors such as image capture devices (cameras/optical sensors), LiDAR and/or RADAR unit(s), satellite-positioning sensor(s) (GPS etc.), motion sensor(s) (accelerometers, gyroscopes etc.) etc., which collectively provide rich sensor data from which it is possible to extract detailed information about the surrounding environment and the state of the AV and any external actors (vehicles, pedestrians, cyclists etc.) within that environment. The sensor outputs typically comprise sensor data of multiple sensor modalities such as stereo images from one or more stereo optical sensors, LiDAR, RADAR etc. Stereo imaging may be used to collect dense depth data, with LiDAR/RADAR etc. proving potentially more accurate but less dense depth data. More generally, depth data collection from multiple sensor modalities may be combined in a way that preferably respects their respective levels of uncertainty (e.g. using Bayesian or non-Bayesian processing or some other statistical process etc.). Multiple stereo pairs of optical sensors may be located around the vehicle e.g. to provide full 360° depth perception.

The perception system 6102 comprises multiple perception components which co-operate to interpret the sensor outputs and thereby provide perception outputs to the prediction system 6104. External agents may be detected and represented probabilistically in a way that reflects the level of uncertainty in their perception within the perception system 6102.

In a simulation context, depending on the nature of the testing—and depending, in particular, on where the stack 6100 is sliced—it may or may not be necessary to model the on-board sensor system 6100. With higher-level slicing, simulated sensor data is not required therefore complex sensor modelling is not required.

The perception outputs from the perception system 6102 are used by the prediction system 6104 to predict future behaviour of external actors (agents), such as other vehicle in the vicinity of the AV.

Predictions computed by the prediction system 6104 are provided to the planner 6106, which uses the predictions to make autonomous driving decisions to be executed by the AV in a given driving scenario. A scenario is represented as a set of scenario description parameters used by the planner 6106. A typical scenario would define a drivable area and would also capture predicted movements of any external agents (obstacles, from the AV's perspective) within the drivable area. The driveable area can be determined using perception outputs from the perception system 6102 in combination with map information, such as an HD (high-definition) map.

A core function of the planner 6106 is the planning of trajectories for the AV (ego trajectories) taking into account predicted agent motion. This may be referred to as maneuver planning. A trajectory is planned in order to carry out a desired goal within a scenario. The goal could for example be to enter a roundabout and leave it at a desired exit; to overtake a vehicle in front; or to stay in a current lane at a target speed (lane following). The goal may, for example, be determined by an autonomous route planner (not shown).

The controller 6108 executes the decisions taken by the planner 6106 by providing suitable control signals to an on-board actor system 6112 of the AV. In particular, the planner 6106 plans manoeuvres to be taken by the AV and the controller 6108 generates control signals in order to execute those manoeuvres.

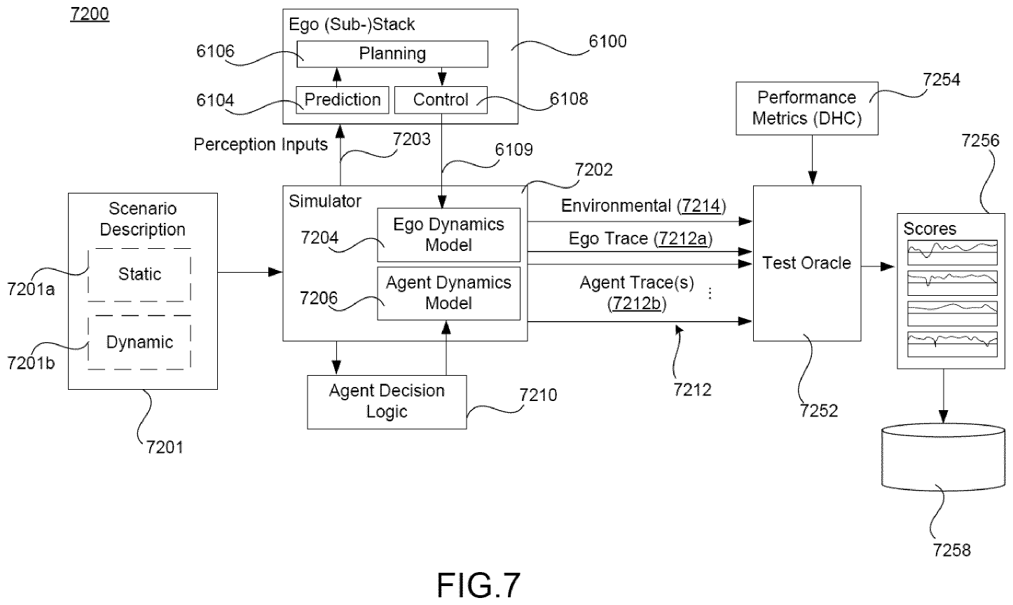

FIG. 7 shows a schematic block diagram of a testing pipeline 7200. The testing pipeline 7200 is shown to comprise a simulator 7202 and a test oracle 7252. The simulator 7202 runs simulations for the purpose of testing all or part of an AV run time stack.

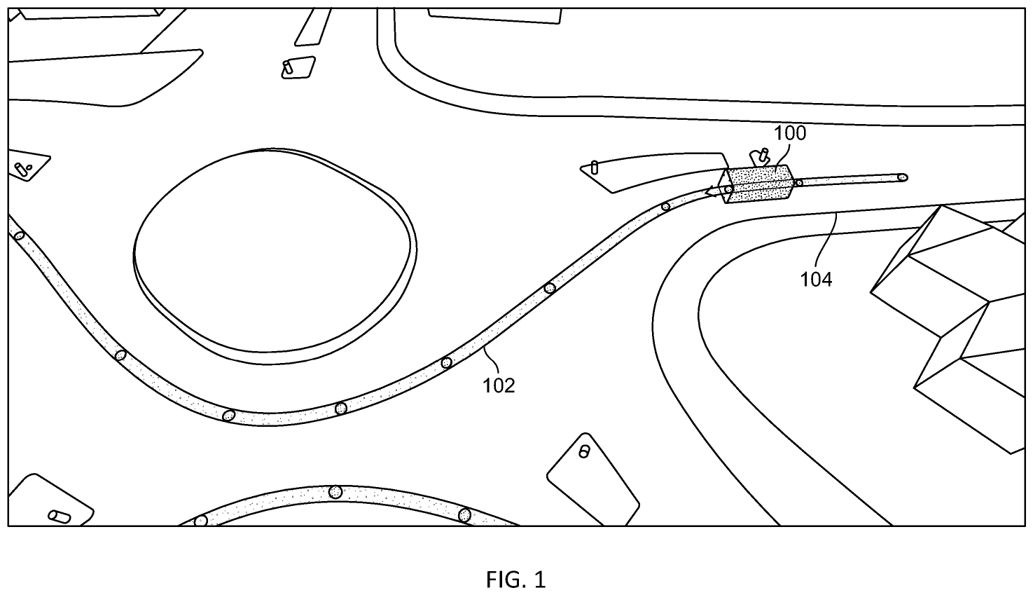

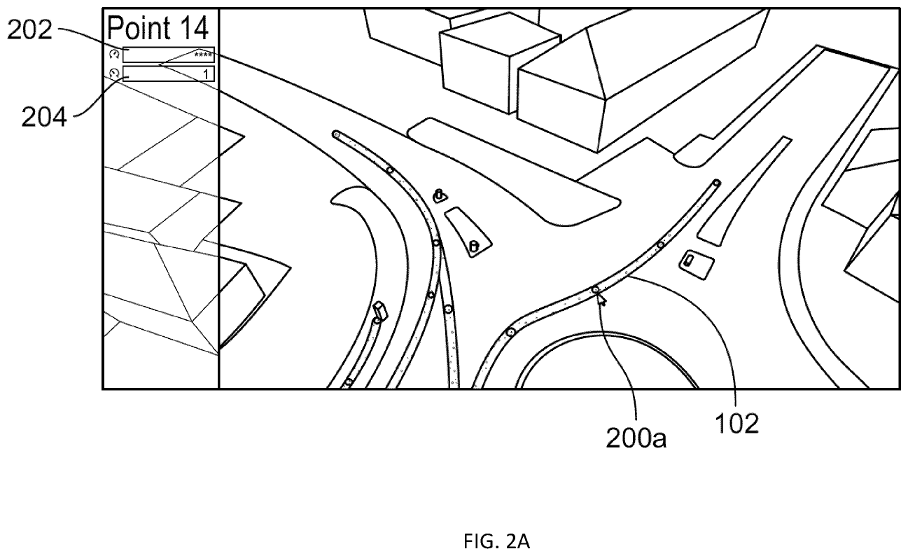

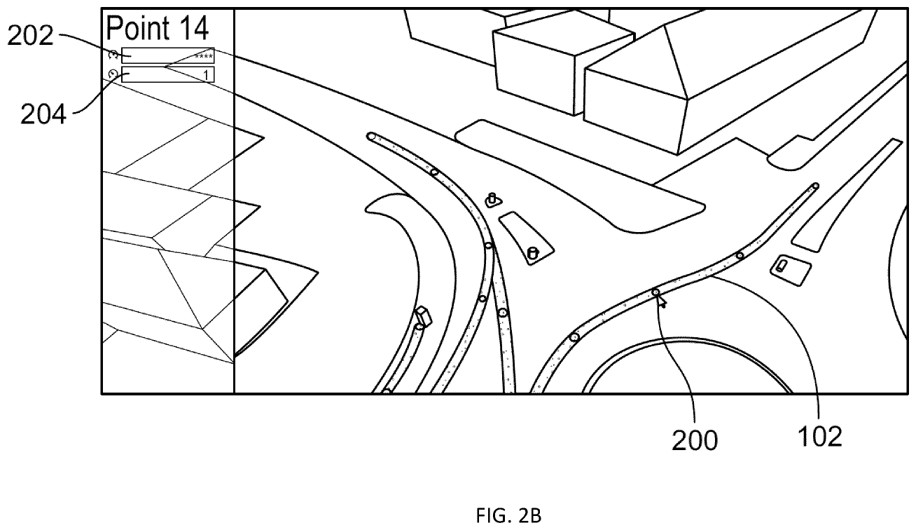

By way of example only, the description of the testing pipeline 7200 makes reference to the runtime stack 6100 of FIG. 1 to illustrate some of the underlying principles by example. As discussed, it may be that only a sub-stack of the run-time stack is tested, but for simplicity, the following description refers to the AV stack 6100 throughout; noting that what is actually tested might be only a subset of the AV stack 6100 of FIG. 1, depending on how it is sliced for testing. In FIG. 2, reference numeral 6100 can therefore denote a full AV stack or only sub-stack depending on the context.

FIG. 7 shows the prediction, planning and control systems 6104, 6106 and 6108 within the AV stack 6100 being tested, with simulated perception inputs 7203 fed from the simulator 7202 to the stack 6100. However, this does not necessarily imply that the prediction system 6104 operates on those simulated perception inputs 7203 directly (though that is one viable slicing, in which case the simulated perception inputs 7203 would correspond in form to the final outputs of the perception system 6102). Where the full perception system 6102 is implemented in the stack being tested (or, at least, where one or more lower-level perception components that operate on raw sensor data are included), then the simulated perception inputs 7203 would comprise simulated sensor data.

The simulated persecution inputs 7203 are used as a basis for prediction and, ultimately, decision-making by the planner 6108. The controller 6108, in turn, implements the planner's decisions by outputting control signals 6109. In a real-world context, these control signals would drive the physical actor system 6112 of AV. The format and content of the control signals generated in testing are the same as they would be in a real-world context. However, within the testing pipeline 7200, these control signals 6109 instead drive the ego dynamics model 7204 to simulate motion of the ego agent within the simulator 7202.

To the extent that external agents exhibit autonomous behaviour/decision making within the simulator 7202, some form of agent decision logic 7210 is implemented to carry out those decisions and drive external agent dynamics within the simulator 7202 accordingly. The agent decision logic 7210 may be comparable in complexity to the ego stack 6100 itself or it may have a more limited decision-making capability. The aim is to provide sufficiently realistic external agent behaviour within the simulator 7202 to be able to usefully test the decision-making capabilities of the ego stack 6100. In some contexts, this does not require any agent decision making logic 7210 at all (open-loop simulation), and in other contexts useful testing can be provided using relatively limited agent logic 7210 such as basic adaptive cruise control (ACC). Similar to the ego stack 6100, any agent decision logic 7210 is driven by outputs from the simulator 7202, which in turn are used to derive inputs to the agent dynamics models 7206 as a basis for the agent behaviour simulations.

A simulation of a driving scenario is run in accordance with a scenario description 7201, having both static and dynamic layers 7201a, 7201b.

The static layer 7201a defines static elements of a scenario, which would typically include a static road layout.

The dynamic layer 7201b defines dynamic information about external agents within the scenario, such as other vehicles, pedestrians, bicycles etc. The extent of the dynamic information provided can vary. For example, the dynamic layer 7201b may comprise, for each external agent, a spatial path to be followed by the agent together with one or both motion data and behaviour data associated with the path.

In simple open-loop simulation, an external actor simply follows the spatial path and motion data defined in the dynamic layer that is non-reactive i.e. does not react to the ego agent within the simulation. Such open-loop simulation can be implemented without any agent decision logic 7210.

However, in “closed-loop” simulation, the dynamic layer 7201b instead defines at least one behaviour to be followed along a static path (such as an ACC behaviour). In this, case the agent decision logic 7210 implements that behaviour within the simulation in a reactive manner, i.e. reactive to the ego agent and/or other external agent(s). Motion data may still be associated with the static path but in this case is less prescriptive and may for example serve as a target along the path. For example, with an ACC behaviour, target speeds may be set along the path which the agent will seek to match, but the agent decision logic 7210 might be permitted to reduce the speed of the external agent below the target at any point along the path in order to maintain a target headway from a forward vehicle.

The output of the simulator 7202 for a given simulation includes an ego trace 7212a of the ego agent and one or more agent traces 7212b of the one or more external agents (traces 7212).

A trace is a complete history of an agent's behaviour within a simulation having both spatial and motion components. For example, a trace may take the form of a spatial path having motion data associated with points along the path such as speed, acceleration, jerk (rate of change of acceleration), snap (rate of change of jerk) etc.

Additional information is also provided to supplement and provide context to the traces 7212. Such additional information is referred to as “environmental” data 7214 which can have both static components (such as road layout) and dynamic components (such as weather conditions to the extent they vary over the course of the simulation).

To an extent, the environmental data 7214 may be “passthrough” in that it is directly defined by the scenario description 7201 and is unaffected by the outcome of the simulation. For example, the environmental data 7214 may include a static road layout that comes from the scenario description 7201 directly. However, typically the environmental data 7214 would include at least some elements derived within the simulator 7202. This could, for example, include simulated weather data, where the simulator 7202 is free to change whether change weather conditions as the simulation progresses. In that case, the weather data may be time-dependent, and that time dependency will be reflected in the environmental data 7214.

The test oracle 7252 receives the traces 7212 and the environmental data 7214, and scores those outputs against a set of predefined numerical performance metrics to 7254. The performance metrics 7254 encode what may be referred to herein as a “Digital Highway Code” (DHC). Some examples of suitable performance metrics are given below.

The scoring is time-based: for each performance metric, the test oracle 7252 tracks how the value of that metric (the score) changes over time as the simulation progresses. The test oracle 7252 provides an output 7256 comprising a score-time plot for each performance metric.

The metrics 7256 are informative to an expert and the scores can be used to identify and mitigate performance issues within the tested stack 6100.

Scenarios for use by a simulation system as described above may be generated in a scenario builder.

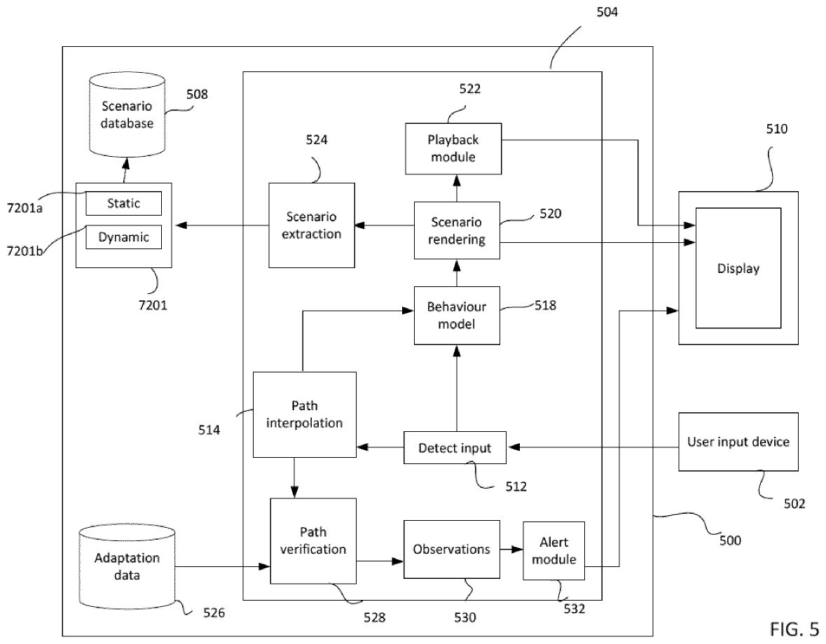

FIG. 5 shows a highly schematic block diagram of a computer implementing a scenario builder, which comprises a display unit 510, a user input device 502, computer storage such as electronic memory 500 holding program code 504, and a scenario database 508. The program code when executed by a suitable computer processor or processors implements multiple modules including an input detection module 512, a path interpolation module 514, a behaviour modelling module 518, a scenario rendering module 520, a scenario extraction module 524, a playback module 522, a path verification module 528, an observation store 530, and an alert module 532. Scenarios are visible to the user on the display 510, with the user able to adjust paths or agent behaviours using one or more user input devices 502, for example, a keyboard and mouse. The action by the user is detected by the user input device which recognises the type of action requested by the user input. If the user has moved points of a path, this data is passed to a path interpolation module 514 which computes an updated smooth path that passes through the user's selected points. The interpolated path is fed to a path verification module 528, which uses the continuous path with adaptation data 526 relating to agent vehicle parameters and vehicle constraints to verify that agent motion along the interpolated path is within vehicle constraints for a given agent. Observations of constraint violations may be output and stored from the path verification module and may be passed to an alert module 532, which produces aural or visual alerts to the user via the user interface. If the user has made any change to the path parameters or behaviour parameters for any agent, this data is passed to the behaviour model 518. The behaviour model 518 takes in both the path and the agent behaviour parameters, and produces agent motion to be rendered within the scene in a playback mode. The scenario rendering module 520 takes in the behaviour data and renders the scene for display with the updated agents and paths. The playback module 522 takes this data and produces a scene that comprises the full motion of all the agents moving according to their defined paths and behaviours. The scenario data 201 is extracted by a scenario extraction module 524. As described above, scenario data 201 for each scenario comprises a static layer 201a, which defines static elements of a scenario, which would typically include a static road layout and a dynamic layer 201b, which defines dynamic information about external agents within the scenario, such as spatial paths and behaviour data. This is exported for each scenario to a scenario database to be passed to the next stage in the pipeline.

FIG. 1 shows an example of one agent defined within a scenario. In offline mode, when the scenario is edited, the ego vehicle may be present in the scene but it does not move or interact with the agents defined for that scenario. This example scenario includes an agent vehicle 100—represented by a cuboid, and a defined path 102 on a road 104 along which the agent is constrained to travel. A feature of the present editor is that the path does not have to follow all or any portion of a road or vehicle track—it can be placed across such roads or partly on a road and partly on a pavement in the scene. For certain actor types (e.g. pedestrians) the path may be mostly off road, but may cross the road, for example at traffic lights. In a given scenario, each agent in the scene is assigned to a path 102 which constrains its direction of travel and a set of path parameters, such as starting position and speed which define its motion along the path.

As described above, the scenario description defines multiple layers which may be used by the simulator during simulation (and by the editing tool in playback mode).

There are multiple layers of configuration that determine the motion of agents of the scenario. The first layer, described above, is configured as a path in the scenario along which the agent moves. The path is defined by a set of at least four points and the speed of the agent at that point and time at which the agent reaches that point may also be configured on creating or editing the path. This layer represents the default motion of the agent, and the agent will travel along the path at the associated speeds by default if not overridden by the configuration of other layers.

A second layer instructs the agent to exhibit behaviours that may or may not override the default speeds dictated by the path points. In one example, the second layer may be configured such that the agent travels at a constant speed, irrespective of the underlying path speeds. In another example, this layer may apply a global modification factor to the speed of the agent along the path such that an agent drives along the path at 80% of the defined speeds set at the configurable path points.

A third layer of configuration includes behaviours that may be assigned to the agent that can depend on the scenario, which may override the default agent speeds set at the points of the path. As explained in more detail below, the speed of the agent may deviate from the assigned speed if the agent has been assigned an overriding behaviour which adapts according to the events of the scenario, for example according to the distance from other agents. However, the agents do not move from their defined path, irrespective of the actions of other agents in the simulation.

Both the path and the configurable behaviours of the agent may be defined by the user during scenario editing. Note that the ‘ path’ describes a spatial trajectory for an agent, as well as path parameters such as agent position and speed at locations along the path. New agents may also be added to the scene and their behaviours defined by the user. Multiple agents may be defined to travel along a shared path. Further details on how the path is configured by a user is described below with reference to FIGS. 2A and 2B.

One reason to generate scenarios is to create events when the simulation is run which would put the ego vehicle on a collision course, so that its decision making behaviour can be assessed in such a scenario. Over recent years, autonomous driving controllers and decision making has improved to such an extent that it is becoming harder and harder to appropriate simulation scenarios of impending collisions from real life scenes. In the present scenario generation tool, scenarios may be edited to provide one or more agent, to move the agents to different starting positions and to modify agent paths and behaviour such that when a simulation is run using the scenario the ego vehicle is caused to make decisions in complex situations. For example, a scenario in which the ego vehicle is approaching a roundabout may be edited to create agents along paths so as to reduce the entry window available to the ego vehicle.

In some existing scenario generation systems, a start and end point can be defined for each agent. Decision making/routing is then used by the agent to define a path and move along it. That path cannot be defined by a user. In other existing scenario generation systems, scenarios may be imported from real life scenes. Such scenes can be marked to define the real vehicle path for conversion to a simulation scene. Such scenarios are time consuming to edit, and can require editing at a script or scenario language level.

The present scenario generation tool provides a user interface which simplifies the creation and editing of scenarios. Agent paths may be created, repositioned or otherwise modified by selecting locations on a display to mark points on the path, adjusting the positions of a set of points supporting the path or by adding new points to an existing path. For example, an agent's path may be created or adjusted so that it crosses the ego vehicle's entrance to a roundabout. A user defines a path by marking a set of these points. When the scenario is run in a simulator, the simulator constrains the motion of the agent based on the path supported by these points.

A path interpolation module 514 in the scenario generation system generates paths based on the set of points which may be defined by the user or imported from a real-life scene. The interpolation module requires a minimum of four points to interpolate a path: two endpoints, and two intermediate points. The interpolation module 514 uses a numerical method to obtain a curve that lies along the set of at least four points. The curve may be calculated such that it satisfies desirable mathematical properties such as differentiability and integrability. A path verification module 528 may determine if an agent travelling along the path in the real world would adhere to kinematic and dynamic constraints.

FIGS. 2A and 2B show an example of modifying the path 102 along which an agent vehicle travels. The path contains a number of points. Each point is associated with a path parameter defining the agent's motion at that point, for example the speed of the agent. The instantaneous motion of the agent is thus defined at each point and numerical methods are used to define the agent's continuous motion along the path based on these points, as described above. In FIG. 2A, one point 200 on a previously created path is shown in one location. The user can move this point to a nearby location by selecting the point, for example by dragging and dropping it using a cursor, as shown in FIG. 2B. Any suitable user input means may be used to control the display to add and move points, for example a touch screen. The path 102 is updated by the path interpolation module to run through the newly defined point position. The user may also define a new instantaneous speed 204 for the agent at the defined point, and the agent's motion along the path will be updated in response to this new speed. The configuration of parameters via the user interface is described in more detail below.

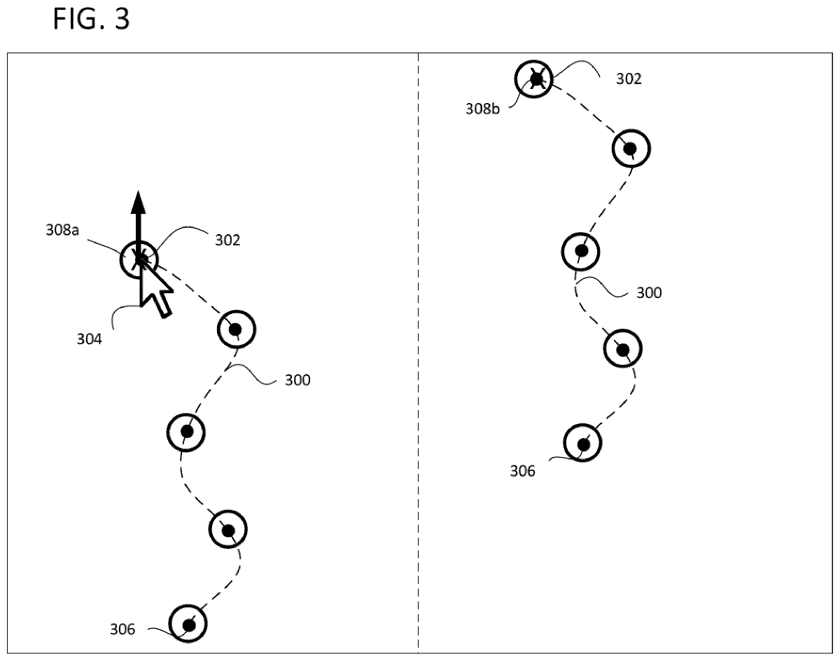

The path may also be updated by moving multiple points simultaneously. An example of this is shown in FIG. 3. In this example, the user uses the cursor 304 to select all points of the path 300 between endpoints 302 and 306. The path is positioned with the endpoint 302 at location 308a. The user may use the cursor 304 to select the path 300 and drag it upwards. This has the effect of moving all selected points, and the associated length of the path 300 upwards such that the endpoint 302 is at location 308b. A path or section of path may also be selected and moved by selecting the endpoints of that section or path.

Some agent behaviours may be defined which allow parameterisation of particular variables that relate to the motion of the agent. An example of such a predefined behaviour that may be assigned to an agent is an ‘Adaptive Cruise Control’ (ACC) behaviour which allows parameterisation of the time or distance gap between two agents on the same driving path. The user may be presented with an interface upon selection of the ACC behaviour that allows the user to select a desired time or distance gap required between the agents. This behaviour may override the target speed determined for the given agents as a path parameter at the points along the agent's path, as mentioned above. The agent, being assigned to this predefined behaviour, may adjust its speed to ensure the requirement for distance between agents is satisfied.

Paths and behaviours are edited by the users while agents are static. A live ‘playback’ mode can be enabled at any time to start each agent at its defined starting position and drive along the defined path according to defined behaviours. This mode simulates the behaviour of each agent within the scenario in real time and allows the user to observe the effect of behaviour and path changes. However, the ego vehicle is not active during this playback as it is done in offline mode. The purpose of playback is to allow the user to observe the changes made to the scenario which will be presented to the ego vehicle in testing at the next stage of the testing pipeline 7200.

The scenario definition described above occurs in offline mode, and so the ego vehicle is not controlled when the scenario switches to playback mode. The ego vehicle may be present in the scenario, but it is static and is not being controlled. This is in contrast to the running of the scenario in the simulator for testing the ego vehicle behaviour—where the ego vehicle drives according to its defined behaviours and interacts with the scenario. This testing occurs at the next stage of the pipeline. The playback mode allows fine tuning of the other agents in the scenario before being exported to this next stage.

Paths and associated default speeds may be adjusted by the user via interaction with an interface which may appear upon completion of a given user action. For example, if the user clicks on a particular point of a path, an interface may appear that includes configurable fields and/or information about that point, for example the speed 204 of the given agent assigned to the path at that point and the time 202 at which this agent reaches the point assuming the agent's defined behaviour does not override the target speed and time of the agent's path (see FIG. 2A, 2B). Path parameters may be entered and adjusted in such configurable fields.

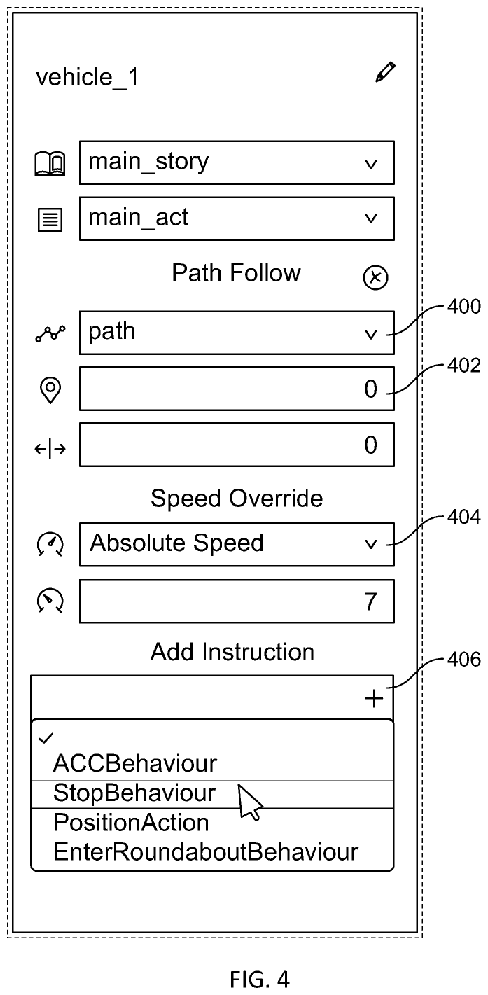

A user may define an agent's behaviours by clicking on the agent itself. An example of the interface presented upon selecting an agent defined to move along a path is shown in FIG. 4. The interface that appears includes information about the agent's behaviour such as the path name 400 to which the agent has been assigned and its position 402 along that path, as well as fields that allow the user to modify that behaviour, including a field 406 to add a predefined behaviour, such as ACC (ACCBehaviour). Other fields may allow the user to change the variable 304 that defines the agent's motion, for example absolute speed.

When the paths and behaviours of the scenario have been defined and edited as desired, triggers may be set to trigger actions based on conditions which define the activation of agent behaviours. These conditions may be spatial, in which a user may define a target region within the road layout such that a given agent falling within that region triggers a predefined action associated with that target. Trigger conditions may also be temporal, where agent behaviours or other actions may be activated at predefined times in the simulation. A user may define the given condition and the action or set of actions the user wishes to activate when that condition is met. A trigger may be defined by a single condition or a set of conditions, where all conditions in the set must be true to trigger the given action.

Conditions can take multiple forms. For example, some conditions may be based on the states of agents within the scene, as in the target region example described above, where the position of the agent is used as a condition for a trigger. Other conditions may be related to values within the scene not linked to agents, such as traffic signals or temporal conditions.

An example of an action may be the activation of a certain behaviour, such as ACC, once it reaches the target region. At this point, the default driving speed dictated by the path speeds or any modifications set for the given agent may be overridden if the agent falls within the predefined distance or time threshold of another agent set by the user when defining the ACC behaviour of that agent.

Another example of an action that may be triggered by a spatial condition is the initialisation of the scenario. This may be triggered by defining a special condition for the ego vehicle, such that the agents of the scenario move from their defined starting positions along their defined paths according to their predefined behaviours only once the ego vehicle moves into a predefined target region of the road layout.

The scenario is exported to be tested at a next stage in the testing pipeline 7200. The static and dynamic layers of the scenario description are uploaded to the scenario database. This may be done via the user interface or programmatically via an API connected to the scenario database.

In a system as described herein, it is possible to use the marked paths to generate a scenario for simulation which also incorporates agents and agent behaviours defined relative to road layouts, or other scene topologies, which may be accessed from a database of scene topologies. Road layouts have lanes etc. defined in them and rendered in the scenario. In such a system, an agent may be directed to travel along a marked path in some sections of a scenario and transition to a ‘ road layout’ topology for other sections of the scenario. A road layout or lane may have certain behaviours associated with it—for example a default speed/acceleration or jerk value for an agent on that road layout.

In this context, the term “behaviour” may be interpreted as follows. A behaviour owns an entity (such as an actor in a scene). Given a higher-level goal, a behaviour yields manoeuvres interactively which progress the entity towards the given goal. The goal could, for example, be to enter a roundabout and leave it at a desired exit; to overtake a vehicle in front; or to stay in a current lane at a target speed (lane following).

For example, an actor in a scene may be given a Follow Lane goal and an appropriate behavioural model. The actor will (in the scenario generated in an editor, and in the resulting simulation) attempt to achieve that goal.

A user may set a configuration for the ego vehicle that captures target speed (e.g. proportion or a target speed for each speed limit zone of a road layout), maximum acceleration values, maximum jerk values etc. In some embodiments, a default speed may be applied for the ego vehicle as the speed limit for a particular speed limit zone of the road layout. A user may be allowed to override this default value with acceleration/jerk values, or set a start point and target speed for the ego vehicle at a trigger point.

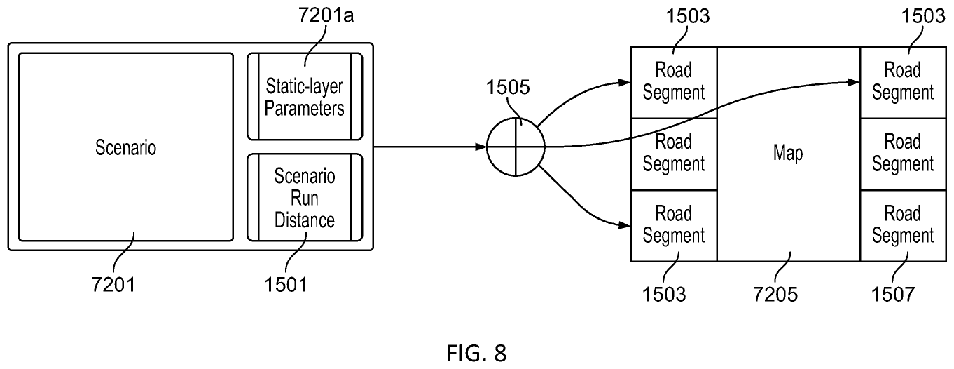

The static layer 7201a defines static elements of a scenario, which would typically include a static road layout. The static layer 7201a of the scenario description 7201 is disposed onto a map 7205, the map loaded from a map database 7207. For any defined static layer 7201a road layout, the system may be capable of recognising, on a given map 7205, all segments of that map 7205 comprising instances of the defined road layout of the static layer 7201a. For example, if a particular map were selected and a ‘roundabout’ road layout defined in the static layer 7201a, the system could find all instances of roundabouts on the selected map 7205 and load them as simulation environments. FIG. 8 is a highly schematic diagram of the process whereby the system recognises all instances of a parametrised static layer 7201a of a scenario 7201 on a map 7205. The parametrised scenario 7201, which may also include data pertaining to dynamic layer entities, is shown to comprise data subgroups 7201a and 1501, respectively pertaining to the static layer defined in the scenario 7201, and the distance requirements of the static layer. By way of example, the static layer parameters 7201a and the scenario run distance 1501 may, when combined, define a 100 m section of a two-lane road which ends at a ‘T-junction’ of a four-lane ‘dual carriageway.’

The identification process 1505 represents the system's analysis of one or more maps stored in a map database. The system is capable of identifying instances on the one or more maps which satisfy the parametrised static layer parameters 7201a and scenario run distance 1501. The maps 7205 which comprise suitable instances of the parametrised road segment may then be offered to a user for simulation.

The system may search for the suitable road segments by comparing the parametrised static layer criteria to existing data pertaining to the road segments in each map. In this case, the system will differentiate a subset of suitable road segments 1503 from a remaining subset of unsuitable road segments 1507.

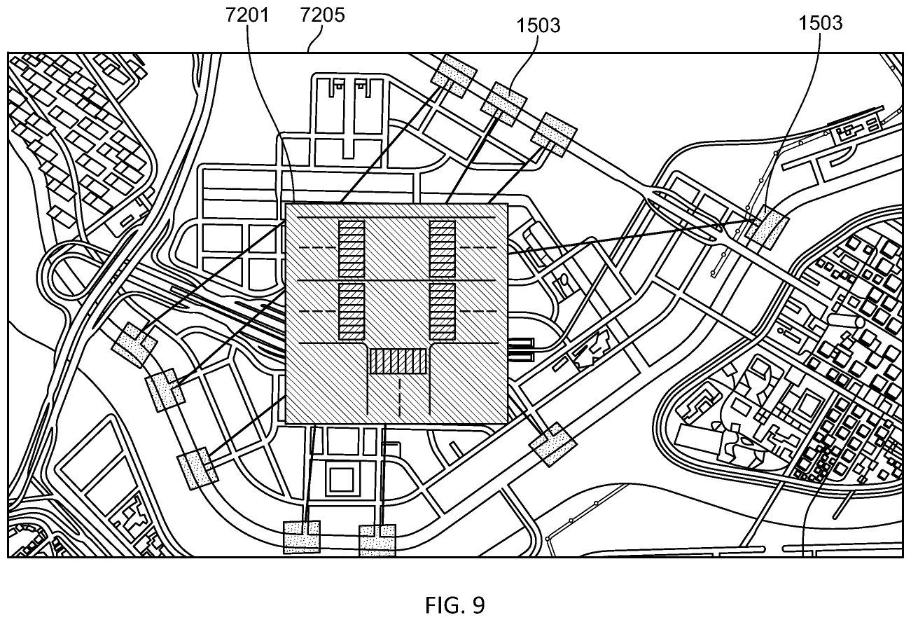

FIG. 9 depicts an exemplary map 7205 comprising a plurality of different types of road segment. As a result of a user parameterising a static layer 7201a and a scenario run distance 1501 as part of a scenario 7201, the system has identified all road segments within the map 7205 which are suitable examples of the parameterised road layout. The suitable instances 1503 identified by the system are highlighted in blue in FIG. 9.

1. A computer implemented method of generating a scenario to be run in a simulation environment for testing the behaviour of an autonomous vehicle, the method comprising:
rendering on a display of a computer device an image of an environment comprising a road layout,
receiving at an editing interface user input for marking multiple locations to create at least one path for an agent vehicle in the rendered image of the environment,
generating at least one path which passes through the multiple locations, and rendering the at least one path in the image,
receiving at the editing interface user input defining at least one behavioural parameter for controlling behaviour of the agent vehicle associated with the at least one path when the scenario is run in a simulation environment, and
recording the scenario comprising the environment, the marked path and the at least one behavioural parameter.

2. The method of claim 1 comprising detecting that a user has selected one of the marked locations and has repositioned it in the image, and generating at least one new path which passes through the existing multiple locations and the repositioned location.

3. The method of claim 1 comprising detecting that a user has highlighted a set of adjacent locations of the multiple locations and repositioned that set, and generating at least one new path which passes through the existing multiple locations and the repositioned set of multiple locations.

4. The method of claim 1 in which the at least one path comprises at least one curved section.

5. The method of claim 1 wherein the step of generating the at least one path comprises interpolating between the marked multiple locations to generate a continuous path which passes through the marked multiple locations.

6. The method of claim 1 comprising detecting that a user has selected one of the marked locations and displaying at the selected location a path parameter at that marked location.

7. The method of claim 6, wherein the path parameter is a default speed for an agent vehicle on the path when the scenario is run in an execution environment.

8. The method of claim 1 wherein the step of rendering the image of the environment on the display comprises accessing an existing scenario from a scenario database, and displaying that existing scenario on the display.

9. The method of claim 8, wherein the existing scenario comprises a static layer for rendering static objects in the environment and a dynamic layer for controlling motion of moving agents in the environment.

10. The method of claim 1 comprising detecting that a user has selected a playback mode at the editing interface and simulating motion of the agent vehicle according to the at least one path and the at least one behavioural parameter in the scenario in the playback mode.

11. The method of claim 1 comprising receiving at the editing interface user input defining a target region, at least one trigger agent, and at last one triggered action, the presence of the target agent in the target region being detected in a simulation when the scenario is run in a simulation environment and causing the triggered action to be effected.

12. The method of claim 1 wherein the at least one path does not conform to any driveable track of the road layout in the scene.

13. The method of claim 1 wherein the road layout comprises at least one traffic junction, and wherein the at least one path for the agent vehicle traverses the junction in a manner likely to create a possible collision event with an ego vehicle on the road layout when the scenario is run in a simulation environment.

14. A computer system for generating a scenario to be run in a simulation environment for testing the behaviour of an autonomous vehicle, the computer system comprising:
a display configured to present an image of an environment comprising a road layout;
one or more processors; and
computer memory comprising instructions executable by the one or more processors to implement:
an editing interface configured to receive user input for marking multiple locations to create at least one path for an agent vehicle in the image of the environment and for defining at least one behavioural parameter for controlling behaviour of the agent vehicle associated with the at least one path when the scenario is run in a simulation environment;
a path generation module configured to generate at least one path which passes through the multiple locations; and
a rendering module configured to render the at least one path in the image, the computer memory configured to record the scenario comprising the environment, the marked path and the at least one behavioural parameter.

15. The system of claim 14 wherein the path generation module is configured to detect that a user has selected one of the marked locations and has repositioned it in the image, and to generate at least one new path which passes through the existing multiple locations and the repositioned location.

16. The system of claim 14 wherein the path generation module is configured to detect that a user has highlighted a set of adjacent locations of the multiple locations and repositioned that set, and to generate at least one new path which passes through the existing multiple locations and the repositioned set of multiple locations.

17. The system of claim 14, wherein the path generation module is configured to generate the at least one path by interpolating between the marked multiple locations to generate a continuous path which passes through the marked multiple locations.

18. (canceled)

19. (canceled)

20. The system of claim 14, the computer memory comprising a scenario database which stores existing scenarios accessible for display, each existing scenario comprising a static layer for rendering static objects in the environment and a dynamic layer for controlling motion of moving agents in the environment.

21. The system of claim 14, configured to detect that a user has selected a playback mode at the editing interface and to simulate motion of the agent vehicle according to the at least one path and the at least one behavioural parameter in the scenario in the playback mode.

22-23. (canceled)

24. A computer program product comprising computer code stored on a non-transitory computer readable medium which, when executed by a computer, carries out steps of;
rendering on a display of a computer device an image of an environment comprising a road layout,
receiving at an editing interface user input for marking multiple locations to create at least one path for an agent vehicle in the rendered image of the environment,
generating at least one path which passes through the multiple locations, and rendering the at least one path in the image,
receiving at the editing interface user input defining at least one behavioural parameter for controlling behaviour of the agent vehicle associated with the at least one path when the scenario is run in a simulation environment, and
recording the scenario comprising the environment, the marked path and the at least one behavioural parameter.
